(19) United States
(12) Patent Application Publication
(10) Pub. No.: US 2020/0107451 A1
(43) Pub. Date: Apr. 2, 2020

(54) METHOD OF PRODUCING WIRING BOARD AND CONDUCTIVE INK

(71) Applicant: FUJIFILM Corporation, Tokyo (JP)

(72) Inventors: Yoshihisa HASHI, Shizuoka (JP); Hiroshi KAWAKAMI, Shizuoka (JP)

(73) Assignee: FUJIFILM Corporation, Tokyo (JP)

(21) Appl. No.: 16/701,159

(22) Filed: Dec. 3, 2019

Related U.S. Application Data
(63) Continuation of application No. PCT/JP2018/021514, filed on Jun. 5, 2018.

(30) Foreign Application Priority Data
Jun. 23, 2017 (JP) 2017-123286

(51) Int. Cl. H05K 3/20; C09D 11/52; H05K 3/12

(52) U.S. Cl. CPC H05K 3/207; H05K 3/125; C09D 11/52

(57) ABSTRACT

Provided is a method of producing a wiring board capable of easily producing a wiring board, and a conductive ink. A method of producing a wiring board according to the present invention is a method of producing a wiring board using a transfer film including a support, a protective layer that is formed on one surface of the support and is peelable from the support, and a receiving layer that is formed on a surface of the protective layer and receives a solvent of a conductive ink including a conductive substance and the solvent, and the method has a wiring pattern forming step of forming a wiring pattern to the transfer film by performing printing using the conductive ink from a surface of the transfer film opposite to a surface on which the support is formed, an adhering step of, after the wiring pattern forming step, causing the surface of the transfer film on which the wiring pattern is formed opposite to the surface on which the support is formed to abut onto a substrate and causing the transfer film to adhere to the substrate, and a peeling step of, after the adhering step, peeling off the support from the transfer film caused to adhere to the substrate to obtain a wiring board.

### CROSS-REFERENCE TO RELATED APPLICATIONS

This application is a Continuation of PCT International Application No. PCT/JP2018/021514 filed on Jun. 5, 2018, which claims priority under 35 U.S.C. § 119(a) to Japanese Patent Application No. 2017-123286 filed on Jun. 23, 2017. The above application is hereby expressly incorporated by reference, in its entirety, into the present application.

### BACKGROUND OF THE INVENTION

### 1. Field of the Invention

The present invention relates to a method of producing a wiring board and a conductive ink.

### 2. Description of the Related Art

A wiring board having a wiring pattern formed on a substrate has been known. Specific examples of a method of forming such a wiring pattern include a method of forming a wiring pattern by etching a metal layer provided on a substrate, a method of forming a wiring pattern using a conductive paste or a conductive ink, and a method of forming a wiring pattern by an electroless plating method.

Among these methods, WO2015/068654A discloses a method of producing a wiring pattern using a conductive ink (a method of producing a wiring board). Specifically, a method in which from a transfer film in which a conductive layer (wiring pattern) obtained using a support film, an adhesive layer, and a conductive ink, and a protective layer are laminated in this order, the support film is peeled off, and then the conductive layer is bonded to the substrate with the adhesive layer interposed therebetween is disclosed (claims 1 and 4).

### SUMMARY OF THE INVENTION

However, it is necessary to form a protective layer for protecting the wiring pattern before a step of causing the transfer film to adhere to the substrate after a wiring pattern forming step in the method of producing a wiring board described in WO2015/068654A. Therefore, there is a problem that the steps from the wiring pattern forming step to the adhering step cannot be smoothly performed and the steps become complicated.

Here, an object of the present invention is to provide a method of producing a wiring board capable of easily producing a wiring board, and a conductive ink.

As a result of intensive studies on the above problem, the present inventors have found that printing is performed on a specific transfer film, in which a support, a protective layer, and a receiving layer are laminated in this order, using a conductive ink from a surface opposite to the support so that a wiring board can be easily produced using the obtained transfer film, and thus the present invention has been achieved.

That is, the present inventors have found that the above object can be achieved by the following configurations.

[1]

A method of producing a wiring board using a transfer film including

a support,

a protective layer that is formed on one surface of the support and is peelable from the support, and

a receiving layer that is formed on a surface of the protective layer and receives a solvent in a conductive ink including a conductive substance and the solvent, the method comprising:

a wiring pattern forming step of forming a wiring pattern on the transfer film by performing printing using the conductive ink from a surface of the transfer film opposite to a surface on which the support is formed;

an adhering step of, after the wiring pattern forming step, causing the surface of the transfer film having the wiring pattern formed thereon opposite to the surface on which the support is formed to abut onto a substrate and causing the transfer film to adhere to the substrate; and

a peeling step of, after the adhering step, peeling off the support from the transfer film caused to adhere to the substrate to obtain a wiring board.

[2]

The method of producing a wiring board according to [1], in which the transfer film further includes a solvent permeation layer that is formed on a surface of the receiving layer and has a void for allowing permeation of the solvent.

[3]

The method of producing a wiring board according to [1] or [2], in which the printing is performed by an ink jet method.

[4]

The method of producing a wiring board according to any one of [1] to [3], in which the adhering step is performed under heating.

[5]

The method of producing a wiring board according to [4], in which a heating temperature in the adhering step is 80° C. or higher.

[6]

The method of producing a wiring board according to any one of [1] to [5], in which a procedure in which a new transfer film on which the wiring pattern obtained by the wiring pattern forming step is formed is caused to adhere to the wiring board obtained in the peeling step, and then the support in the new transfer film is peeled off is repeatedly performed so that a plurality of wiring patterns are laminated on the substrate.

[7]

The method of producing a wiring board according to any one of [1] to [6], in which, after the wiring pattern forming step, the wiring pattern is exposed to light.

[8]

The method of producing a wiring board according to any one of [1] to [7], in which the conductive substance is a metal nanowire having an aspect ratio of 200 or more.

[9]

The method of producing a wiring board according to any one of [1] to [8], in which the conductive ink further includes a compound represented by Formula (I) described later, in Formula (I) described later, X represents a gold atom, a palladium atom, or a platinum atom.

[10]

The method of producing a wiring board according to [9], in which the conductive substance is a metal nanowire having an aspect ratio of 200 or more, and a mass ratio of the metal nanowire with respect to the compound represented by Formula (I) described above is more than 10 and less than 1000.

[11]

The method of producing a wiring board according to any one of [1] to [10], in which the conductive ink further includes magnetic particles.

[12]

The method of producing a wiring board according to any one of [1] to [11], in which the conductive ink further includes a coloring material.

[13]

A conductive ink comprising: a solvent; a compound represented by Formula (I) described later; and a metal nanowire having an aspect ratio of 200 or more,

in Formula (I) described later, X represents a gold atom, a palladium atom, or a platinum atom.

[14]

The conductive ink according to [13], in which a mass ratio of the metal nanowire with respect to the compound represented by Formula (I) described above is more than 10 and less than 1000.

[15]

The conductive ink according to [13] or [14], further comprising: magnetic particles.

[16]

The conductive ink according to any one of [13] to [15], further comprising: a coloring material.

As shown below, according to the present invention, it is possible to provide a method of producing a wiring board capable of easily producing a wiring board protected with an insulating layer, and a conductive ink. Particularly, according to the present invention, it is possible to provide a method of producing a wiring board which does not require processes such as development, etching, and baking.

### BRIEF DESCRIPTION OF THE DRAWINGS

FIG. 1 is a cross-sectional view schematically showing an example of a transfer film used in a production method according to the present invention.

FIG. 2 is a view conceptually showing an example of a configuration of a receiving layer in the transfer film used in the production method according to the present invention.

FIG. 3 is a view conceptually showing a configuration of a solvent permeation layer in the transfer film used in the production method according to the present invention.

FIG. 4 is a view schematically showing an example of an adhering step in the production method according to the present invention.

FIG. 5 is a view schematically showing an example of a peeling step in the production method according to the present invention.

FIG. 6 is a view schematically showing an example of an adhering step in the production method according to the present invention.

FIG. 7 is a view schematically showing an example of a peeling step in the production method according to the present invention.

FIG. 8 is a view schematically showing an example of an adhering step in the production method according to the present invention.

FIG. 9 is a view schematically showing an example of a peeling step in the production method according to the present invention.

### DESCRIPTION OF THE PREFERRED EMBODIMENTS

Hereinafter, the present invention will be described.

The description of the constituent elements described below may be made based on typical embodiments of the present invention, but the present invention is not limited to such embodiments.

In the present invention, a numerical range expressed using “to” means a range including numerical values described before and after “to” as a lower limit value and an upper limit value.

In the present invention, “(meth)acryl” means a general term for “acryl” and “methacryl”.

A method of producing a wiring board according to an embodiment of the present invention (hereinafter, also referred to as “the production method”) is a method of producing a wiring board using a transfer film (hereinafter, also referred to as “specific transfer film”) having a support, a protective layer that is formed on one surface of the support and is peelable from the support, and a receiving layer that is formed on a surface of the protective layer and receives a solvent in a conductive ink including a conductive substance and the solvent.

In addition, the production method has a wiring pattern forming step of forming a wiring pattern on the specific transfer film by printing using the conductive ink from a surface of the transfer film opposite to the surface on which the support is formed,

an adhering step of, after the wiring pattern forming step, causing the surface of the specific transfer film having the wiring pattern formed thereon opposite to the surface on which the support is formed to abut onto a substrate and causing the specific transfer film to adhere to the substrate, and

a peeling step of, after the adhering step, peeling off the support from the specific transfer film caused to adhere to the substrate to obtain a wiring board.

In the production method, since printing is performed on the specific transfer film having the protective layer formed in advance, a step of forming a protective layer is not necessarily performed between the wiring pattern forming step and the adhering step, and the steps from printing to adhering can be smoothly performed. In this manner, according to the production method, it is possible to produce a wiring board with a simple step. Further, according to the production method, wiring can be caused to directly adhere to an object that cannot be developed, etched and baked, for example, a surface of an apparatus.

Hereinafter, first, materials to be used in the production method will be described in detail and then each step will be described in detail.

[Specific Transfer Film]

The specific transfer film used in the production method has a support, a protective layer that is formed on one surface of the support and is peelable from the support, and a receiving layer that is formed on a surface of the protective layer and receives a solvent in a conductive ink including a conductive substance and the solvent.

The specific transfer film may also have a solvent permeation layer that is formed on a surface of the receiving layer and has voids for allowing permeation of the solvent in the conductive ink.

Hereinafter, the specific transfer film will be described in detail with reference to the drawings, taking a case where the specific transfer film has a solvent permeation layer as an example.

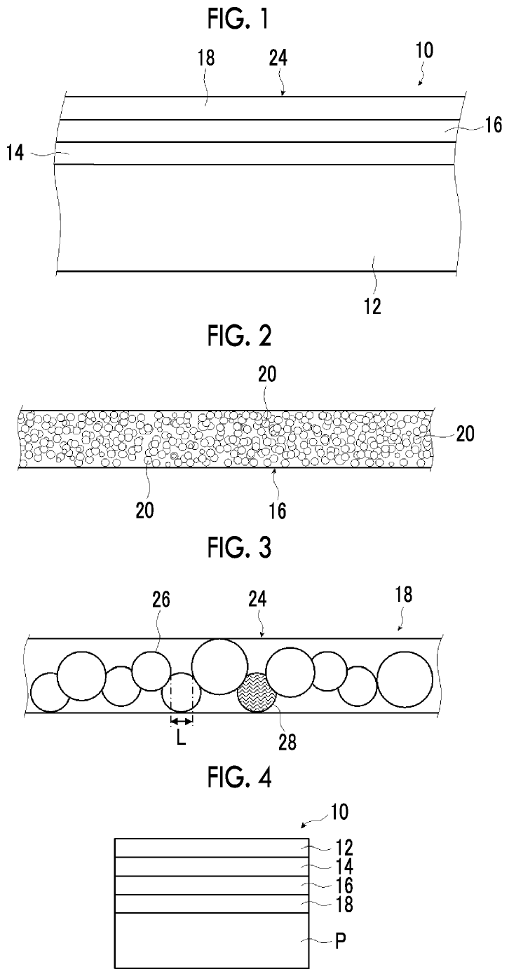

FIG. 1 is a cross-sectional view schematically showing an example of the specific transfer film. As shown in FIG. 1, a transfer film 10 has a support 12, a protective layer 14 that is formed on one surface of the support 12, a receiving layer 16 that is formed on a surface of the protective layer 14, and a solvent permeation layer 18 that is formed on a surface of the receiving layer 16.

As described later, after printing is performed on the transfer film 10 from the solvent permeation layer 18 side using a conductive ink, the solvent permeation layer 18 is caused to adhere to a substrate P and then the support 12 is peeled off from the protective layer 14. A laminate including the solvent permeation layer 18, the receiving layer 16, and the protective layer 14 is transferred to the substrate P to form a wiring pattern on the substrate P.

Accordingly, in a state in which the laminate including the solvent permeation layer 18, the receiving layer 16, and the protective layer 14 is transferred to the substrate P, the protective layer 14 becomes a surface and the solvent permeation layer 18 becomes the substrate P side.

(Support)

The support 12 supports the protective layer 14, the receiving layer 16, and the solvent permeation layer 18 until the transfer film 10 is caused to adhere to the substrate P.

As the support 12, known various sheet-like materials (films) capable of supporting the protective layer 14, the receiving layer 16, and the solvent permeation layer 18 can be used. Particularly, in a case where an adhering step described later is performed under heating (that is, a case of heating adhesion), a support 12 having sufficient heat resistance is preferably used.

Specific examples of the support 12 include resin films formed of various resin materials. Specific examples of resin materials that can be used for the support 12 include polyester-based resins such as polyethylene terephthalate (PET) and polyethylene naphthalate (PEN), polycarbonate resins, acrylic resins, methacrylic resins, and polyimide resins.

Although the thickness of the support 12 is not particularly limited, the protective layer 14, the receiving layer 16, and the solvent permeation layer 18 can be supported until the adhering step described later is performed, and after the transfer film 10 is caused to adhere to the substrate P, the thickness at which the support can be properly peeled off without causing breakage, or the like can be set appropriately according to the forming material.

Specifically, the thickness of the support 12 is preferably 20 to 200 μm and more preferably 50 to 130 μm.

(Protective Layer)

The protective layer 14 is formed on one surface of the support 12.

The protective layer 14 is a layer for protecting the receiving layer 16 after a peeling step described later.

The protective layer 14 preferably includes a polymer.

The glass transition temperature (Tg) of the polymer that can be included in the protective layer 14 is preferably 0° C. or higher, more preferably 20° C. or higher, and still more preferably 30° C. or higher. In a case where the Tg of the polymer is 0° C. or higher, in the peeling step described later, the peelability between the support 12 and the protective layer 14 is further improved.

The upper limit value of the Tg of the polymer that can be included in the protective layer 14 is preferably 80° C. or lower. In a case where the Tg of the polymer is 80° C. or lower, there are such advantages that the protective layer 14 is satisfactorily formed (film-formed), and the selection range of the support 12 is widened since the film formation temperature can be lowered.

The Tg of the polymer may be measured by a known method, numerical values described in various documents may be used, and in a case of using a commercially available polymer, numerical values described in catalogs may be used or numerical values calculated from the polymer composition may be used. As a specific example of a method of measuring the glass transition temperature, a measurement method according to Japanese industrial standards (JIS) K 7121 by differential scanning calorimetry analysis may be used.

The solubility parameter (SP value) of the polymer that may be included in the protective layer 14 is preferably 8.5 (cal/cm³)^{1/2} or more and more preferably 9.0 (cal/cm³)^{1/2} or more. In a case where the SP value of the polymer is 8.5 (cal/cm³)^{1/2} or more, since the protective layer 14 can be formed with a polymer with high polarity and strong molecular cohesion, there are such advantages that the scratch resistance of the protective layer 14 is improved, the tensile resistance of the protective layer 14 is high, and the peelability is improved.

The solubility parameter of the polymer may be measured by a known method, numerical values described in various documents may be used, and in a case of using a commercially available polymer, numerical values described in catalogs may be used.

In addition, the SI unit of the solubility parameter is [(MPa)^{1/2}]. The [(cal/cm³)^{1/2}] can be converted to [(MPa)^{1/2}] which is the SI unit by multiplying by 2.05. That is, it is “[(MPa)^{1/2}]=[(cal/cm³)^{1/2}]×2.05”.

As described above, wiring pattern formation is performed on the substrate P using the transfer film 10 by, in a state in which the solvent permeation layer 18 is caused to abut onto the substrate P, causing the solvent permeation layer 18 to adhere to the substrate P, and then peeling off the support 12.

The lower limit of the thickness of the protective layer 14 is not particularly limited and the thickness at which the receiving layer 16 can be sufficiently protected may be appropriately set according to the forming material of the protective layer 14.

The thickness of the protective layer 14 is preferably 1 μm or more and more preferably 2 μm or more. The protective layer 14 may have a single layer structure or a multilayer structure.

As the polymer included in the protective layer 14, known various polymers can be used.

Examples thereof include a urethane-based polymer, an acrylic polymer, a vinyl acetate-based polymer, a vinyl chloride-based polymer, a rubber-based polymer, a styrene-based polymer, a silicone-based polymer, an ester-based polymer, an amide-based polymer, and a copolymer including a plurality of repeating units constituting these polymers. Among these, from the viewpoint of further excellent peelability of the support 12, a urethane-based polymer is preferable.

In addition, as the polymer included in the protective layer 14, a commercially available product may be used.

Specific examples of the polymer having a Tg of 0° C. or higher among commercially available products include SUPER FLEX 170 (urethane-based polymer), SUPER FLEX 820 (urethane-based polymer), SUPER FLEX 830HS (urethane-based polymer), and SUPER FLEX 870 (urethane-based polymer) manufactured by Dai-Ichi Kogyo Seiyaku Co., Ltd.; VINYBLAN 287 (vinyl chloride-acrylic polymer), VINYBLAN 900 (vinyl chloride-acrylic polymer), VINYBLAN 2684 (acrylic polymer), VINYBLAN 2685 (acrylic polymer), VINYBLAN 2687 (acrylic polymer), and VINYBLAN 715S (vinyl chloride-based polymer) manufactured by Nissin Chemical Industry Co., Ltd.; SUMIKAFLEX 752HQ (ethylene-vinyl acetate copolymer resin emulsion), SUMIKAFLEX 808HQ (ethylene-vinyl acetate-vinyl chloride copolymer resin emulsion), SUMIKAFLEX 850HQ (ethylene-vinyl acetate-vinyl chloride copolymer resin emulsion), and SUMIKAFLEX 830 (ethylene-vinyl acetate-vinyl chloride copolymer resin emulsion) manufactured by Sumika Chemitex Co., Ltd.; Nipol LX433C (styrene butadiene rubber), Nipol LX2507H (styrene butadiene rubber), Nipol LX416 (styrene butadiene rubber), Nipol LX814 (acrylic polymer), and Nipol LX855EX1 (acrylic polymer) manufactured by Zeon Corporation; and MOWINYL 742A (acrylic polymer), MOWINYL 1711 (acrylic polymer), MOWINYL 6520 (acrylic polymer), MOWINYL 7980 (acrylic polymer), MOWINYL 081F (vinyl acetate-ethylene-based copolymer), and MOWINYL 082 (vinyl acetate-ethylene-based copolymer) manufactured by The Nippon Synthetic Chemical Industry Co., Ltd.

The protective layer 14 may include two or more polymers and preferably includes two or more polymers both having a Tg of 0° C. or higher.

In a case where protective layer 14 includes two or more polymers, it is possible to obtain the transfer film 10 in which the transferability and scratch resistance of the protective layer is excellent by expressing the properties of the respective polymers. For example, by using a urethane-based polymer and an ethylene-vinyl acetate-vinyl chloride copolymer in combination, it is possible to obtain the transfer film 10 in which the peelability of the support 12 and the scratch resistance of the protective layer 14 are excellent.

The content of the polymer having a Tg of 0° C. or higher is preferably 20% by mass or more, more preferably 30% by mass or more, and particularly preferably 50% by mass or more with respect to the total mass of the protective layer 14. It is preferable to set the content of the polymer having a Tg of 0° C. or higher to 20% by mass or more from the viewpoint that the peelability between the support 12 and the protective layer 14 is improved, the scratch resistance of the protective layer 14 is improved, and the bendability (flexibility) is improved.

The protective layer 14 may include a surfactant.

In a case where the protective layer 14 includes a surfactant, the peelability between the support 12 and the protective layer 14 can be improved.

As the surfactant, known surfactants can be used according to the forming material of the protective layer 14. Specific examples of the surfactant include non-ionic surfactants such as ethers such as polyoxyethylene nonyl phenyl ether, polyoxyethylene octyl phenyl ether, polyoxyethylene dodecyl phenyl ether, polyoxyethylene oleyl ether, polyoxyethylene lauryl ether, and polyoxyethylene alkyl ether (for example, EMULGEN series such as EMULGEN 108, 109P, and the like, manufactured by Kao Corporation, SOFTANOL EP-5035, 7085, and 9050, manufactured by NIPPON SHOKUBAI Co., Ltd., and PLURONIC L-31, L-34, and L-44 manufactured by ADEKA Corporation);

esters such as polyoxyethylene oleate, polyoxyethylene distearate, sorbitan laurate, sorbitan monostearate, sorbitan monooleate, sorbitan sesquioleate, polyoxyethylene monooleate, and polyoxyethylene stearate; and

polyglycol ethers such as polyoxyethylene acetylene glycol ether, polyoxyethylene distyrenated phenyl ether, and polyoxyethylene tribenzylated phenyl ether (for example, SURFYNOL 104, 104PG50, 105PG50, 82, 420, 440, 465, and 485, and OLFINE STG, manufactured by Nissin Chemical Industry Co., Ltd.).

The content of the surfactant is preferably 0.01% to 5% by mass and more preferably 0.1% to 2% by mass with respect to the total mass of the protective layer 14.

If necessary, the protective layer 14 may include components other than the above components, and for example, various additives such as a wax, an inorganic pigment, an ultraviolet absorber, an antioxidant, and the like may be included.

(Receiving Layer)

The receiving layer 16 is formed on the surface of the protective layer 14.

The receiving layer 16 is a layer for receiving a solvent (water and/or organic solvent) included in a conductive ink. Specifically, the receiving layer 16 receives a solvent which is included in a conductive ink and is permeated into the solvent permeation layer 18, mainly passing through the solvent permeation layer 18. The receiving layer 16 can receive components (which may be liquid or solid; examples thereof include a conductive substance and a coloring material) that have passed through the solvent permeation layer 18 as well as a solvent included in a conductive ink.

As the receiving layer 16 include a layer formed using a polymer that swells by receiving a solvent or a layer having voids (micropores) formed by fixing fine particles insoluble in a solvent (dispersion medium) included in a conductive ink by a binder may be used.

In the example in FIG. 1, although the case where the transfer film 10 has the solvent permeation layer 18 has been described, in a case where the transfer film 10 does not have the solvent permeation layer 18, a conductive substance (and a coloring material used if necessary) is held in the receiving layer 16.

FIG. 2 is a view conceptually showing an example of the configuration of the receiving layer 16.

The receiving layer 16 shown in FIG. 2 is formed by fixing a plurality of receiving particles 20 insoluble in a conductive ink by a binder and the ink is received in each gap of the receiving particles 20.

In a case where the conductive ink includes a coloring material (described later), as the receiving particles 20, it is preferable to use receiving particles which do not cause aggregation with a fixing agent for fixing the coloring material in the conductive ink between the receiving particles 20, and for example, a material with nonpolarity or low polarity may be used.

Specific examples of the receiving particles 20 include polymer fine particles such as polyolefin, acryl, polystyrene, and polyester fine particles, and inorganic fine particles such as calcium carbonate, kaolin, aluminum silicate, calcium silicate, colloidal silica, alumina, and aluminum hydroxide fine particles.

Specific examples of the binder for fixing the receiving particles 20 include gelatin, polyvinyl alcohol, polyvinylpyrrolidone, alginic acid, aqueous polyester, and a water-soluble polymer such as an aqueous acrylic resin. In a case where the conductive ink includes a metal nanowire, polyvinylpyrrolidone that can be stabilized in an aqueous ink and a solvent ink is preferable.

In a case where the conductive ink includes a coloring material, the coloring material is received by the receiving layer 16. At this time, when the receiving layer 16 itself has a light scattering ability, in a case where a wiring pattern is built up (for example, a case where wiring board is used for the purpose of attaching a backlight to the background or the like), the light is scattered, brightness and saturation may be reduced. Therefore, the receiving layer 16 preferably has a low light scattering ability and is transparent.

In consideration of this point, in order to suppress light scattering and light absorption and make the receiving layer 16 transparent, as the receiving particles 20, it is preferable to use ink receiving particles which are colorless and has a particle size smaller than the wavelength of visible light or which is colorless and has a refractive index difference with the binder for fixing the receiving particles 20 of 0.1 or less. As a combination in which the refractive index difference between the receiving particles 20 and the binder is 0.1 or less, for example, a combination in which silica is used as the receiving particles 20 and polyvinyl alcohol (PVA) is used as the binder is exemplified.

The thickness of the receiving layer 16 is not particularly limited and may be appropriately set according to the forming material of the receiving layer 16 such as the receiving particles 20. Specifically, the thickness of the receiving layer 16 is preferably 5 to 50 μm and more preferably 10 to 40 μm.

The receiving layer 16 may have a single layer structure or a multilayer structure.

The ink absorption capacity of the receiving layer 16 is preferably 3 to 40 mL/m² and more preferably 6 to 30 mL/m². As the ink absorption capacity of the receiving layer 16 increases, the electrical conductivity increases.

Here, the ink absorption capacity is a value obtained the following measurement method. A test piece is obtained by cutting an ink jet recording medium to have a size of 10 cm square, 1 mL of diethylene glycol is added dropwise onto an ink receiving layer of the obtained test piece, then excess diethylene glycol that cannot be absorbed is wiped off, and an ink absorption capacity (mL/m²) is obtained from a difference in the mass of the receiving layer before and after the dropwise addition and the specific gravity of diethylene glycol.

(Solvent Permeation Layer)

The solvent permeation layer 18 is formed on the surface of the receiving layer.

The solvent permeation layer 18 is a layer having voids for allowing permeation of the solvent included in the conductive ink.

In addition, after a wiring pattern is printed on the transfer film 10, the solvent permeation layer 18 has a function of holding a conductive substance (for example, metal nanowire) that can be included in the conductive ink. Among the components included in the conductive ink, the solvent permeation layer 18 may hold a component that cannot pass through the voids.

In addition, after a wiring pattern is printed on the transfer film 10, the solvent permeation layer 18 may function as an adhesion layer (adhesive layer or pressure sensitive adhesive layer) for causing the transfer film 10 to adhere to the substrate P.

FIG. 3 conceptually shows the configuration of the solvent permeation layer 18.

In the solvent permeation layer 18 shown in FIG. 3, the voids for allowing permeation of the solvent included in the conductive ink are formed by gaps L of a plurality of thermoplastic resin particles 26 which are present in a dispersed manner over the entire layer. Each gap L formed by the thermoplastic resin particles 26 is formed continuously in a thickness direction and thus the voids penetrating the solvent permeation layer 18 in the thickness direction are formed.

In the solvent permeation layer 18, the solvent included in the conductive ink attached to a surface 24 passes through the voids penetrating the permeation layer in the thickness direction and thus the solvent included in the conductive ink passes through the solvent permeation layer 18 and is supplied to the receiving layer 16.

In addition, the conductive substance included in the conductive ink is attached to the surfaces of the thermoplastic resin particles 26 or caught in the voids, and thus is held in the solvent permeation layer 18. A part of the conductive substance may pass through the voids and supplied to the receiving layer 16.

In the solvent permeation layer 18, it is preferable that the gap L (inter-particle distance) between the thermoplastic resin particles 26 is controlled to be 0.1 μm or more by selecting the particle size and particle distribution of the thermoplastic resin particles 26 or the like not to prevent permeation of the conductive ink.

In addition, in the solvent permeation layer 18, it is preferable that the particle size of the thermoplastic resin particle 26 is 0.1 to 10 μm so as not to prevent permeation of the conductive ink and not to diffuse the conductive ink in a direction parallel with the principal surface of the transfer film 10.

The thermoplastic resin particles 26 is preferably formed of a material having a softening temperature of 40° C. to 100° C. so as not to prevent permeation of the ink due to softening or film formation at environmental temperature such as room temperature while the transfer film 10 is caused to adhere to the substrate P.

As such a material, for example, a styrene-based copolymer resin of styrene, acryl, and butadiene, or the like, a polyolefin-based resin, a resin formed of polymethacrylic acid and a derivative thereof, an acrylic ester-based resin, a polyacrylamide-based resin, a polyester-based resin, and a polyamide-based resin can be used.

Further, it is preferable that in the solvent permeation layer 18, tackifier particles 28 (tackifying resin particles 28) for improving adhesion to the substrate P are included in a dispersed manner.

As the material constituting the tackifier particles 28, rosins, rosin esters, alicyclic resins, phenol resins, chlorinated polyolefin resins, urethane resins, and the like can be used. Incidentally, the tackifier can also be contained inside the thermoplastic resin particles 26 without being dispersed in the solvent permeation layer 18 as particles. For example, in a case of heating adhesion, by incorporating the tackifier into the thermoplastic resin at the time of heating adhesion, it is possible to strengthen the adhesion with the substrate P.

The solvent permeation layer 18 is disposed closer to the substrate P than to the receiving layer 16 which carries the wiring board in a state in which the transfer film 10 is transferred to the substrate P. That is, in a case where the conductivity of the wiring board formed on the substrate P is confirmed by the transfer film 10, the solvent permeation layer 18 becomes an underlayer of the receiving layer 16 which holds the image.

Therefore, for example, the solvent permeation layer 18 may be formed as a white layer or light scattering layer by mixing organic resin fine particles including a white inorganic pigment, white polycarbonate, and/or (meth)acrylic resin, light scattering particles, or the like with the solvent permeation layer 18. Thus, since a wiring pattern excellent in wiring pattern visibility and sharpness can be obtained, in a case where the wiring board (wiring pattern) to which the transfer film 10 is transferred is clearly reflected, the solvent permeation layer is suitable.

The thickness of the solvent permeation layer 18 is not particularly limited and the thickness which allows adhesion with the substrate P with a sufficient adhesive force may be appropriately set according to the forming material of the solvent permeation layer 18 such as the thermoplastic resin particles 26. Specifically, the thickness of the solvent permeation layer 18 is preferably 0.5 to 5 μm and more preferably 0.8 to 3 μm.

The solvent permeation layer 18 may have a single layer structure or a multilayer structure.

(Method of Producing Transfer Film)

The transfer film 10 can be prepared by a known method according to the forming material of each layer. Hereinafter, an example of a method of producing the transfer film 10 is shown.

First, a resin film which becomes the support 12 is prepared.

On the other hand, a coating liquid for forming the protective layer 14 obtained by dissolving or dispersing a compound (for example, a polymer having a Tg of 0° C. or higher), which becomes the protective layer 14, in ion exchange water or the like is prepared.

In addition, a coating liquid for forming the receiving layer 16 obtained by dissolving or dispersing a compound, which becomes the image receiving layer 16, such as ink receiving particles 20 (for example, silica particles), and a binder, in ion exchange water or the like, is prepared.

Further, a coating liquid for forming the solvent permeation layer 18 obtained by dissolving or dispersing a compound, which becomes the solvent permeation layer 18, such as the thermoplastic resin particles 26 (for example, polyethylene particles) or a binder, in ion exchange water and the like, is prepared.

Additionally, first, the coating liquid for forming the protective layer 14 is applied to the surface of the support 12 and is dried to form the protective layer 14. The coating liquid may be applied by a known method such as a bar coating method, a die coating method, and dipping (dip coating). In addition, the coating liquid may be dried by a known method according to the coating liquid such as heating and drying using hot air or a heater. In this regard, both the receiving layer 16 and the solvent permeation layer 18 are similar.

Next, the coating liquid for forming the receiving layer 16 is applied to the surface of the formed protective layer 14 and dried to form the receiving layer 16.

Further, the coating liquid for forming the solvent permeation layer 18 is applied to the surface of the formed receiving layer 16 and dried to form the solvent permeation layer 18. Thus, the transfer film 10 is obtained.

[Substrate]

The substrate P is not particularly limited and various known articles such as resin molded articles (for example, films) such as various sensors such as cards and wearable wiring boards, metal products such as silicon wafers, and products made of paper such as coated cardboards and corrugated cardboards can be used.

In addition, as a material constituting resin molded articles, polyester-based resins such as polyethylene terephthalate (PET) and polyethylene naphthalate (PEN), polycarbonate resins, acrylic resins, methacrylic resins, and polyimide resins may be used.

Among these substrates P, large three-dimensional objects, films and paper with low heat resistance, and the like are susceptible to processes such as development, etching, and baking, and thus may not be used in methods of related art. However, in the production method, wiring can be formed without performing the above process. Accordingly, in the production method, as the substrate P, a large three-dimensional object, a film and paper with low heat resistance, and the like can be suitably used.

[Conductive Ink]

The conductive ink in the present invention includes a conductive substance and a solvent. The conductivity means electrical conductivity.

(Conductive Substance)

The conductive substance is not particularly limited as long as the substance has conductivity. Examples thereof include metals such as copper, chromium, lead, nickel, gold, platinum, palladium, silver, tin, and zinc, and alloys of these metals.

The conductive substance may have any shape such as a spherical shape and wire shape, but from the viewpoint of further excellent conductivity, a wire shape is preferable. It is preferable that the conductive substance has a wire shape (that is, metal nanowire) formed of a metal or metal alloy.

The metal nanowire is preferably formed of silver and a metal other than silver. As a metal other than silver, metals that are nobler than silver are preferable, gold, platinum, and palladium are more preferable, and gold is still more preferable.

The metal other than silver may be alloyed with silver, and a silver nanowire that becomes the core may be covered with the metal. However, it is preferable that the silver nanowire is covered with the metal. In a case where the silver nanowire is covered with the metal, the metal other than silver does not necessarily have to cover the entire surface of the silver nanowire that becomes the core, and only a part of the surface of the silver may be covered.

Since the ionization energy of the metal that is nobler than silver is higher than that of silver, the silver nanowire is alloyed with the metals or the metal is introduced by surface plating. Thus, the oxidation resistance of the metal nanowire can be improved. In addition, in a case where a small amount of the metal that is nobler than silver (specifically, preferably 0.5 to 10 parts by mass and more preferably 1 to 5 parts by mass with respect to 100 parts by mass of silver) is included in the silver nanowire, the heat resistance of the nanowire can be improved.

The content of each metal atom in the metal nanowire can be measured using, for example, an inductively coupled plasma (ICP) emission spectroscopic analyzer after the metal nanowire is dissolved with an acid or the like.

The shape of the metal nanowire is not particularly limited and can be appropriately selected according to the purpose. For example, any shape such as a columnar shape, a rectangular parallelepiped shape, or a columnar shape with a polygonal cross section can be used.

From the viewpoint of easy conduction and low wiring pattern resistance, and the resistance of the wiring pattern can be lowered, the major axis average length of the metal nanowire is preferably 1 μm or more, more preferably 5 μm or more, and still more preferably 10 μm or more. The upper limit value of the major axis average length of the metal nanowire is 1000 μm or less from the viewpoint of dispersion stability and jetting stability of ink jet printing.

The minor axis average length of the metal nanowire is preferably 3 nm or more and less than 200 nm and more preferably 5 to 100 nm. In a case where the minor axis average length of the metal nanowire is 3 nm or more, the heat resistance is excellent, and in a case where the minor axis average length of the metal nanowire is less than 200 nm, the metal nanowire has a sufficient surface area. Thus, the conductivity of the metal nanowire is further improved.

The major axis average length of the metal nanowire is a value obtained by randomly selecting 200 metal nanowires from a TEM image including a plurality of metal nanowires observed using a transmission electron microscope (TEM) and arithmetically averaging the major axis length of each metal nanowire. Similarly, the minor axis average length of the metal nanowire is a value obtained by randomly selecting 200 metal nanowires from a TEM image including a plurality of metal nanowires and arithmetically averaging the minor axis length of each metal nanowire.

The aspect ratio of the metal nanowire is preferably 200 or more. When an aspect ratio of the metal nanowire is 200 or more, in a case where a wiring pattern is printed by an ink jet method, the electrical connection of the wiring pattern is more easily achieved and as a result, the resistance can be further lowered.

The upper limit value of the aspect ratio of the metal nanowire is usually 10000 or less.

The aspect ratio of the metal nanowire means a ratio of the major axis average length with respect to the minor axis average length of the metal nanowire.

The aspect ratio of the metal nanowire and the content of the metal other than silver can be controlled by appropriately selecting the concentration of a metal salt, an inorganic salt, and an organic acid (or salt), the kind of solvent at the time of particle formation, the concentration of a reducing agent, the rate of addition of each component, temperature, and the like in the method of producing the metal nanowire.

In addition, as a specific example of the method of producing the metal nanowire, a method described in paragraphs 0019 to 0024 of JP2011-149092A may be used.

The content of the conductive substance is preferably 0.1% to 20% by mass and more preferably 0.3% to 15% by mass with respect to the total mass of the conductive ink.

In the related art, it is preferable for the heat resistance of the metal nanowire to have the following heat resistance.

Specifically, in a case where the wiring pattern (wiring board) formed using the metal nanowire is used for various devices, in the production process of various devices, generally, the heat resistance that can withstand in a lamination (paneling) step with a thermoplastic resin at 150° C. or higher and in a solder reflow step for a wiring portion at 220° C. or higher is required. With respect to the production process, from the viewpoint of providing a transparent conductor having high reliability, it is preferable that the metal nanowire has heat resistance to heating at 240° C. for 30 minutes and more preferably has heat resistance to heating at 240° C. for 60 minutes.

The silver nanowire is deformed so as to have a shape close to a sphere shape in order to minimize the surface area in a case where the nanowire is heated. Specifically, the nanowire may be disconnected and deformed such that each small piece has a shape close to a sphere shape, in a case of being exposed to heat and high humidity for a long period of time, the resistance value may be increased, and thus conductivity may not be attained.

For such problems, even in a case of using the silver nanowire, by combining the adhering step and the peeling step in the production method, a strong insulating layer (protective layer) is formed on the surface of the wiring board after the peeling step. Thus, in a case where the nanowire is exposed to an 85% relative humidity (RH) environment at 85° C. for 120 hours, the fluctuation in the resistance value can be suppressed.

(Solvent)

For example, the solvent has a function of dispersing or dissolving the component included in the conductive ink or controlling the viscosity of the conductive ink.

Examples of the solvent include water and organic solvents. Either water or an organic solvent may be used alone, or both may be used in combination. In a case where water and an organic solvent are used in combination, it is preferable to use an organic solvent that is miscible with water.

The organic solvent is not limited but an alcohol-based solvent having a standard boiling point of 50° C. to 250° C. is preferable, and an alcohol-based solvent having a standard boiling point of 55° C. to 200° C. is more preferable. In a case where an alcohol-based solvent having a standard boiling point of 50° C. to 250° C. is used, there are advantages in that the jetting stability is improved and the drying speed of the conductive ink is improved in printing by an ink jet method.

Alcohol-based compounds are not particularly limited and can be selected appropriately according to the purpose. Examples thereof include methanol, ethanol, ethylene glycol, diethylene glycol, triethylene glycol, polyethylene glycol 200, polyethylene glycol 300, glycerin, propylene glycol, dipropylene glycol, 1,3-propanediol, 1,2-butanediol, 1,4-butanediol, 1,5-pentanediol, 1-ethoxy-2-propanol, ethanolamine, diethanolamine, 2-(2-aminoethoxy)ethanol, and 2-dimethylamino isopropanol, and ethanol and ethylene glycol are preferable. These alcohol based compounds may be used singly or in combinations of two or more.

From the viewpoint of suppressing jetting failure due to drying of the conductive ink on a jetting head of an ink jet recording device, among these organic solvents, an organic solvent having a boiling point of 100° C. or higher is preferably included in the conductive ink. The content of the organic solvent having a boiling point higher than 100° C. is preferably 5% to 30% by mass and more preferably 8% to 25% by mass with respect to the total mass of the conductive ink.

(Compound Represented by Formula (I))

The conductive ink preferably includes a compound represented by Formula (I) (hereinafter, also referred to as “compound (I)”). The compound (I) is also referred to as a noble metal thiolglucose. By containing the compound (I) in the conductive ink, wiring pattern migration can be suppressed.

In the present invention, migration (electromigration) means that a conductive substance such as a metal is ionized and the ions migrate.

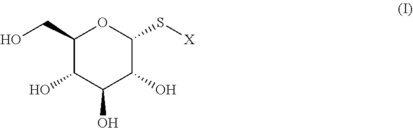

In Formula (I), X represents a gold atom, a palladium atom or a platinum atom, and from the viewpoint of obtaining the stability and the conductivity of the wiring pattern, a gold atom is preferable.

Here, among the conductive substances, a metal nanowire (particularly, silver nanowire) is very useful since conductivity can be exhibited even in a case where a wiring pattern is formed at room temperature. However, since metal generally has a property that the surface is oxidized, as the surface area of the nano region is increased, migration tends to occur, and as a result, the wiring pattern may be disconnected.

For such a problem, since migration can be suppressed in a case of using the compound (I), it is possible to suppress the disconnection of the wiring pattern. Accordingly, it is preferable that the metal nanowire and the compound (I) are used in combination in the conductive ink.

The content of the compound (I) is preferably 0.005% to 0.5% by mass, more preferably 0.01% to 0.3% by mass, and still more preferably 0.02% to 0.1% by mass with respect to the total mass of the conductive ink. In a case where the content of the compound (I) is within the above range, the above effect is further exhibited.

In a case where the conductive substance included in the conductive ink is a metal nanowire, the mass ratio of the metal nanowire with respect to the compound (I) is preferably more than 10 and less than 1000, more preferably more than 20 and less than 150, and still more preferably more than 50 and less than 120. In a case where the mass ratio is more than 10, since the action of sulfur atoms in the molecular skeleton of the compound (I) can be suppressed, the conductivity of the wiring pattern is further improved. In a case where the mass ratio is less than 1000, the durability of the wiring board is further improved.

(Magnetic Particle)

The conductive ink may include magnetic particles. In a case where a magnetic field is applied to the jetting head when wiring pattern printing is performed by an ink jet method, the magnetic particles are arranged along the magnetic field. Accordingly, since the conductive substance (particularly, metal nanowire) is arranged along the magnetic field, the conductive substance is not easily clogged in the jetting nozzle. As a result, the jetting stability of the conductive ink is improved.

Specific examples of the magnetic particles include iron oxide particles constituted of one or more of magnetite (Fe₃O₄) and maghemite (γ-Fe₂O₃).

The content of the magnetic particles is preferably 0.1% to 20% by mass, more preferably 0.5% to 10% by mass, and still more preferably 1% to 5% by mass with respect to the total mass of the conductive ink.

The magnetic particles may be added to the conductive ink in the form of a magnetic fluid that is dispersed in a liquid medium.

(Coloring Material)

The conductive ink may include a coloring material. Thus, the wiring pattern can have a color corresponding to the substrate or a drawing by the wiring pattern can be performed.

Examples of the coloring material include dyes and pigments, and dyes are preferable since the dyes are easily dissolved in the solvent and held in the receiving layer. The kind of dyes and pigments are not particularly limited, and known materials may be used.

The content of the coloring material is preferably 0.02% to 10% by mass, more preferably 0.1% to 5% by mass, and still more preferably 0.2% to 3% by mass with respect to the total mass of the conductive ink.

The content of the coloring material is preferably 0.1 to 100 parts by mass, more preferably 1 to 50 parts by mass, and still more preferably 2 to 20 parts by mass with respect to 100 parts by mass of the conductive substance in the conductive ink.

(Other Components)

The conductive ink may include components other than the above components to the extent not to influence the conductivity. Examples of other components include a polymerizable compound, a sulfidation inhibitor, a corrosion inhibitor, a surfactant, an antioxidant, a viscosity adjuster, and a preservative.

Among these, it is preferable that the conductive ink includes a corrosion inhibitor among these components. By containing a corrosion inhibitor, a higher rust prevention effect may be exhibited.

As the corrosion inhibitor, azoles are preferable, and specific examples thereof include benzotriazole, tolyltriazole, mercaptobenzothiazole, mercaptobenzotriazole, mercaptobenzotetrazole, (2-benzothiazolyl thio)acetic acid, 3-(2-benzothiazolyl thio)propionic acid, alkali metal salts, ammonium salts, and amine salts thereof. These corrosion inhibitors may be used singly or in combination of two or more thereof.

The corrosion inhibitor may be added after being dissolved in a solvent suitable for the conductive ink.

In a case where the conductive ink contains the corrosion inhibitor and the compound (I), the mass ratio of the corrosion inhibitor with respect to the compound (I) is preferably 0.01 or less.

From the viewpoint of minimizing the decrease in conductivity due to metal corrosion, it is preferable that the conductive ink does not contain inorganic ions such as alkaline metal ions, alkaline earth metal ions, and halogenated ions.

(Physical Properties of Conductive Ink)

The electrical conductivity of the conductive ink is preferably 1 mS/cm or less, more preferably 0.1 mS/cm or less, and still more preferably 0.05 mS/cm or less. The electrical conductivity can be measured using a portable electric conductivity meter CM-31P (product name, manufactured by DKK-TOA Corporation).

The viscosity of the conductive ink at 25° C. is preferably 0.5 to 100 mPa·s and more preferably 1 to 50 mPa·s. The viscosity can be measured using VISCOMATE VM-1G-L (product name, manufactured by Tokyo Garasu Kikai Co., Ltd. (TGK)).

[Method of Producing Wiring Board]

An example of this production method will be described in detail with reference to FIGS. 1 to 5.

First, the conductive ink is jetted from a nozzle of a jetting head of an ink jet recording device and is jetted to the surface 24 of the solvent permeation layer 18 of the transfer film 10. The solvent included in the jetted conductive ink passes through the gaps between the thermoplastic resin particles 26, is permeated into the solvent permeation layer 18, and is held in the receiving layer 16. On the other hand, the conductive substance (for example, metal nanowire) included in the jetted conductive ink is attached to the surfaces of the thermoplastic resin particles 26, is sandwiched in the gaps between the thermoplastic resin particles 26, and is fixed. In this manner, the wiring pattern is held in the solvent permeation layer 18 (wiring pattern forming step).

As a printing method, an ink jet method has been described as an example from the viewpoint of being able to suitably cope with on-demand printing, but a known printing method such as a screen printing method may be used.

After the wiring pattern forming step, the solvent permeation layer 18 of the transfer film 10 on which the wiring pattern is formed is caused to abut onto the substrate P, and the transfer film 10 and the substrate P are laminated. Next, by heating the laminate from the support 12 if necessary while pressing the transfer film 10 and the substrate P, if necessary, the transfer film 10 (solvent permeation layer 18) and the substrate P are heated and caused to adhere to each other (heating bonding, heating pressure sensitively adhesion) (adhering step, refer to FIG. 4).

Here, the heating temperature in the heating adhesion is preferably 80° C. or higher, more preferably 90° C. or higher, and still more preferably 100° C. or higher. By performing heating adhesion at 80° C. or higher, the adhesiveness between the transfer film 10 and the substrate P is further improved.

The lower limit value of the heating temperature is preferably 150° C. or lower, more preferably 140° C. or lower, and still more preferably 130° C. or lower. Particularly, at a heating temperature of 130° C. or lower, there is an advantage that in a case where the substrate P is a PET film, precipitation of a low molecular weight substance (for example, oligomer) present in the PET or the like can be suppressed or deformation of the substrate P can be suppressed.

The temperature refers to the maximum reaching film surface temperature of the transfer film in the adhering step.

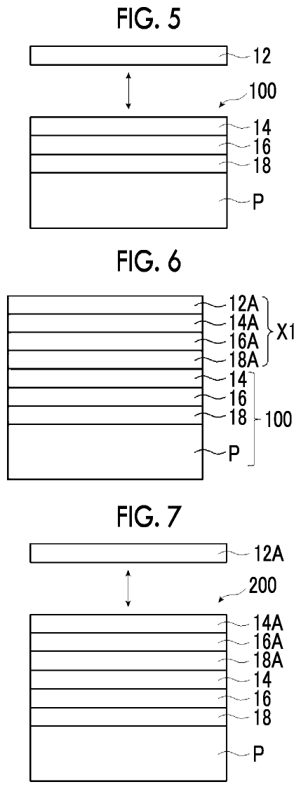

After the adhering step, the support 12 is peeled off from the transfer film 10 caused to adhere to the substrate P. Thus, as shown in FIG. 5, a wiring board 100 formed by transferring laminate in which the solvent permeation layer 18 on which the wiring pattern is formed, the receiving layer 16, and the protective layer 14 are laminated in this order onto the substrate P to form is obtained (peeling step, refer to FIG. 5).

Although not implemented in the above production method, it is preferable that after the wiring pattern forming step, the wiring pattern is exposed. Thus, the wiring pattern is photo-sintered and the resistance of the wiring pattern is lowered.

Exposure is not particularly limited as long as exposure is performed after the wiring pattern forming step, and it is preferable to perform exposure before the peeling step.

The exposure is performed, for example, by irradiation with ultraviolet rays using a product name “PulseForge 3300” manufactured by Novacentrix.

Regarding the exposure conditions, the exposure may be performed according to known conditions so that the transfer film 10 is not deformed. For example, the irradiation energy is preferably 1 to 20 J/cm², the pulse irradiation time is preferably 10 to 10000 seconds, and the number of irradiation is preferably 5 to 30 times.

In the production method, as shown in FIGS. 4 to 5, the wiring board 100 may be produced using a cut sheet-like transfer film, but the wiring board may be produced using a long transfer film by, while moving the transfer film and the substrate in the longitudinal direction of the transfer film at the same speed, causing the transfer film to adhere to the substrate.

In FIGS. 4 and 5, the example in which the wiring board 100 formed by laminating one set of laminate (the solvent permeation layer 18 on which the wiring pattern is formed, the receiving layer 16, and the protective layer 14) on the substrate P is produced is shown, but in the production method, a wiring board (multilayer wiring board) formed by laminating two or more sets of laminates on the substrate P may be produced.

That is, as another embodiment of the production method, a method of obtaining a wiring board by repeatedly performing a procedure of a new transfer film wiring pattern is formed and is obtained by the wiring pattern forming step is caused to adhere to the wiring board obtained in the peeling step, and then the support in the new transfer film is peeled off so that a plurality of wiring patterns are laminated on the substrate may be used. Thus, a wiring board (multilayer wiring board) formed by laminating a plurality of wiring patterns on the substrate is obtained.

Hereinafter, an example in which a wiring board formed by laminating two or more sets of laminates on the substrate P is produced will be described in detail with reference to the drawings.

First, a new transfer film X1 on which a wiring pattern is formed, which can be obtained by the above wiring pattern forming step, is prepared (preparation step).

As shown in FIG. 6, the transfer film X1 in which a protective layer 14A, a receiving layer 16A, and a solvent permeation layer 18A on which the wiring pattern is formed are formed is laminated on one surface of a support 12A in this order.

Next, the solvent permeation layer 18A of the transfer film X1 is caused to abut onto the protective layer 14 of the wiring board 100 obtained by the peeling step described in FIG. 5 and the transfer film X1 and the wiring board 100 are caused to adhere to each other (an adhering step of the transfer film X1, refer to FIG. 6).

Next, the support 12A is peeled off from the transfer film X1 (a peeling step using the transfer film X1, refer to FIG. 7). Thus, as shown in FIG. 7, a wiring board 200 formed by laminating two sets of laminates having the wiring pattern on the substrate P is obtained.

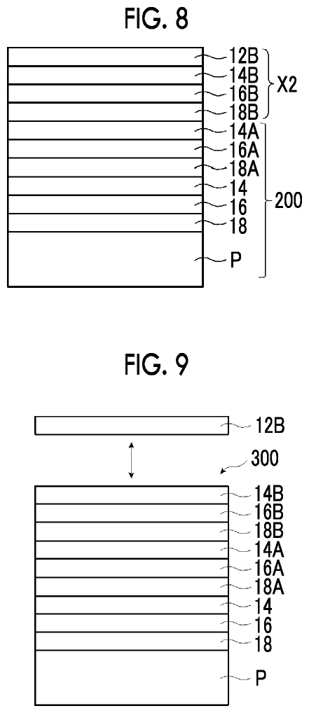

Here, in the preparation step, in a case where two or more transfer films are prepared, the wiring board can be further multi-layered. This embodiment will be described using FIGS. 8 and 9.

As shown in FIG. 8, the transfer film X2 is formed by laminating a protective layer 14B, a receiving layer 16B, and a solvent permeation layer 18B on which a wiring pattern is formed on one surface of a support 12B in this order.

First, after the peeling step using the transfer film X1, the solvent permeation layer 18B of the transfer film X2 is caused to abut onto the protective layer 14A of the wiring board 200 and the transfer film X2 and the wiring board 200 are caused to adhere to each other (an adhering step using the transfer film X2, refer to FIG. 8).

Next, the support 12B is peeled off from the transfer film X2 (a peeling step using the transfer film X2, refer to FIG. 9). Thus, as shown in FIG. 9, a wiring board 300 in which three or more laminates having the wiring pattern are laminated on the substrate P is obtained.

In this manner, in a case of repeating the steps shown in FIGS. 8 and 9, a wiring board in which a random number of laminates having a wiring pattern are laminated can be obtained.

The wiring board obtained by the production method is suitably used for, for example, forming electronic circuits that hold the security of card-like items such as boarding cards for trains and buses, credit cards, electronic money cards, identification (ID) cards, card keys, and various point cards, complex radio frequency (RF) chips to enhance confidentiality of various information, and antenna circuits for energy harvest.

Particularly, the wiring board is preferably a thin film.

### EXAMPLES

Hereinafter, the present invention will be described in detail with reference to examples. However, the present invention is not limited thereto.

[Production of Metal Nanowire]

Three kinds of silver nanowires (A) to (C) shown in Table 1 were produced and stored in a mixed solvent containing water and an organic solvent.

(Production of Silver Nanowire (A))

2.5 g of polyvinylpyrrolidone (PVP) was put into 60 g of ethylene glycol at room temperature, and while the materials were stirred at 500 rpm, the temperature was raised to 135° C. for 10 minutes. Then, stirring was continued and maintained at 135° C.

After 10 minutes had elapsed since the temperature reached 135° C., 0.006 g (0.1 mmol) of sodium chloride dissolved in 0.6 g of ethylene glycol in a separate container in advance was added. After 3 minutes had elapsed since sodium chloride was added, 0.85 g (5.0 mmol) of silver nitrate dissolved in 7.65 g of ethylene glycol in a separate container in advance was added.

After silver nitrate was added, the stirring rate was changed to 100 rpm, the mixture was held at 135° C. for 3.0 hours to complete heating. In this state, the mixture was naturally cooled until the temperature dropped to 80° C. or lower.

After the temperature reached 80° C. or lower, some of the solution (slurry after reaction) was collected in a centrifuge tube, washing was performed by addition of distilled water, and centrifugation was performed at 3000 rpm for 5 minutes. After removing the supernatant after the centrifugation, methanol was added to wash the precipitate, and the methanol dispersion liquid was centrifuged at 2500 rpm for 5 minutes.

After removing the supernatant after centrifugation, methanol was added again to wash the precipitate, and the methanol dispersion liquid was centrifuged at 1500 rpm for 10 min. After removing the supernatant after this centrifugation, the precipitate was dispersed at a ratio of water:propanol:monoethylene glycol=2.5:2.5:1, and the dispersion liquid containing a silver nanowire (A) was stored in a screw tube bottle.

This precipitate is an aggregate of the silver nanowire. In this manner, the silver nanowire (A) shown in Table 1 was obtained. The concentration of the solid contents was 20% by mass.

(Production of Silver Nanowires (B) and (C))

A dispersion liquid containing a silver nanowire (B) and a dispersion liquid containing a silver nanowire (C) were produced in the same operation as in the production of the silver nanowire (A).

However, the silver nanowire (B) was produced under the condition that metal nitrate ions were further added. In addition, the silver nanowire (C) was produced under the condition using tetrabutylammonium chloride instead of sodium chloride as a chlorine source.

For each silver nanowire obtained, using a transmission electron microscope (TEM), the major axis average length and the minor axis average length were calculated, and the aspect ratio (major axis average length/minor axis average length) was calculated based on the obtained values. Each value is shown in Table 1.

TABLE 1

| | Silver nanowire | | |
|---|---|---|---|
| Kind | (A) | (B) | (C) |
| Major axis average | 10 | 10 | 220 |
| length [μm] | | | |
| Minor axis average | 50 | 250 | 100 |
| length [μm] | | | |
| Aspect ratio | 200 | 40 | 2200 |

[Production of Conductive Ink]

[Conductive Ink 1]

20 ml of ethylene glycol and 5 ml of ethanol were added to 75 ml of the dispersion liquid containing the silver nanowire (A) to prepare a conductive ink 1.

After the preparation, ultrasonic dispersion was performed for 20 minutes and then stirring was performed using at 2500 rpm for 20 minutes “T 18 digital ULTRA-TURRAX” (product name) manufactured by IKA to complete redispersion.

The viscosity of the conductive ink 1 was 15 mPa·s (25° C.) or less. The viscosity was measured using “VISCOMATE VM-1G” (product name) manufactured by CBC Materials Co. Ltd.

[Conductive Ink 2]

20 ml of ethylene glycol and 15 mg of a compound (aurothioglucose) represented by Formula (I-1) dissolved in 5 ml of ethanol were added to 75 ml of the dispersion liquid containing the silver nanowire (A) so that the mass ratio of the metal nanowire with respect to aurothioglucose was 100, and thus a conductive ink 2 was prepared.

Operations other than this operation were the same as in the production of the conductive ink 1 to obtain the conductive ink 2.

The viscosity of the conductive ink 2 was 15 mPa·s (25° C.) or lower (measured under the same conditions as in the measurement of the conductive ink 1).

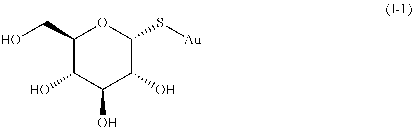

[Conductive Ink 3]

A conductive ink 3 was obtained in the same manner as in the production of the conductive ink 2 except that instead of using the dispersion liquid containing the silver nanowire (A), the dispersion liquid containing the silver nanowire (B) was used.

The viscosity of the conductive ink 3 was 17 mPa·s (25° C.) or lower (measured under the same conditions as in the measurement of the conductive ink 1).

[Conductive Ink 4]

A conductive ink 4 was obtained in the same manner as in the production of the conductive ink 2 except that instead of using the dispersion liquid containing the silver nanowire (A), the dispersion liquid containing the silver nanowire (C) was used.

The viscosity of the conductive ink 4 was 17 mPa·s (25° C.) or lower (measured under the same conditions as in the measurement of the conductive ink 1).

[Conductive Ink 5]

A conductive ink 5 was obtained in the same manner as in the production of the conductive ink 2 except that 1.5 g of a magnetic fluid (MSG-W11, manufactured by FeroTec) in terms of a solid content was added.

MSG-W11 is a fluid formed by dispersing magnetic particles (a mixture of magnetite (Fe₃O₄) particles and maghemite (γ-Fe₂O₃) particles) in an aqueous liquid medium, and the average particle diameter is 10 nm.

The viscosity of the conductive ink 5 was 17 mPa·s (25° C.) or less (measured under the same conditions as in the measurement of the conductive ink 1).

[Conductive Ink 6]

A silver nanoparticle ink (product name “NBSIJ-MU01”) manufactured by Mitsubishi Paper Industries was used as a conductive ink 6.

The viscosity of the conductive ink 6 was 2.3 mPa·s (25° C.) or lower (measured under the same conditions as in the measurement of the conductive ink 1).

[Conductive Ink 7]

A conductive ink 7 was obtained in the same manner as in the production of the conductive ink 2 except that instead of using the compound (aurothioglucose) represented by Formula (I-1), a compound represented by Formula (II) was used.

The viscosity of the conductive ink 7 was 17 mPa·s (25° C.) or lower (measured under the same conditions as in the measurement of the conductive ink 1).

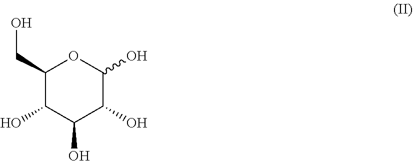 [SMILES: OC[C@H]1OC(O)[C@H](O)[C@@H](O)[C@@H]1O]

[Conductive Ink 8]

A conductive ink 8 was obtained in the same manner as in the production of the conductive ink 2 except that the compound (aurothioglucose) represented by Formula (I-1) was added so that the mass ratio of the compound (aurothioglucose) represented by Formula (I-1) with respect to the metal nanowire was 11.

The viscosity of the conductive ink 8 was 17 mPa·s (25° C.) or lower (measured under the same conditions as in the measurement of the conductive ink 1).

[Conductive Ink 9]

A conductive ink 9 was obtained in the same manner as in the production of the conductive ink 2 except that the compound (aurothioglucose) represented by Formula (I-1) was added so that the mass ratio of the compound (aurothioglucose) represented by Formula (I-1) with respect to the metal nanowire was 999.

The viscosity of the conductive ink 9 was 17 mPa·s (25° C.) or lower (measured under the same conditions as in the measurement of the conductive ink 1).

[Production of Transfer Film A]

As described below, a transfer film A was produced.

[Support]

As the support 12, a PET film having a width of 1000 mm, a thickness of 100 μm, and a length of 100 m (product name “COSMOSHINE A4100”, manufactured by Toyobo Co., Ltd.) was used.

[Protective Layer]

<Preparation of Coating Liquid for Forming Protective Layer>

The following materials were stirred and mixed to prepare a coating liquid for forming a protective layer 14.

| | | |
|---|---|---|
| Ion exchange water | 690 | parts by mass |
| Urethane-based resin emulsion | 300 | parts by weight |
| (product name “SUPER FLEX 170”, | | |
| manufactured by Daiichi Kogyo Seiyaku Co., | | |
| Ltd., polymer concentration: 33% by mass, glass | | |
| transition temperature (Tg) of polymer: 75° C., | | |
| solubility parameter (SP value) of polymer: 10.0 | | |
| (cal/cm³)^{1/2}) | | |
| 10% by mass aqueous surfactant solution | 10 | parts by mass |
| (polyoxyethylene lauryl ether, product name | | |
| “EMULGEN 109P”, manufactured by Kao | | |
| Corporation) | | |

<Formation of Protective Layer>

The coating liquid for forming a protective layer was applied to the highly smooth surface of the support 12 using a #20 wire bar in a coating amount of 35 g/m², and dried at 100° C. for 2 minutes. Thus, the protective layer 14 was formed on the surface of the support 12. The thickness of the formed protective layer 14 was 3 μm.

[Receiving Layer]

<Preparation of Dispersion Liquid>

A mixed liquid having the following composition was prepared.

| | | |
|---|---|---|
| Vapor phase method silica particles | 5.7 | parts by mass |
| (AEROSIL300SF75, manufactured by Nippon | | |
| Aerosil Co., Ltd.) | | |
| Ion exchange water | 22.7 | parts by mass |
| Dispersant | 0.5 | parts by mass |
| (SHAROL DC-902P, manufactured by | | |
| Dai-ichi Kogyo Seiyaku Co., Ltd. | | |
| concentration: 51.5% by mass, charge | | |
| density: 6.6 meq/g) | | |
| Zirconyl acetate | 0.3 | parts by mass |
| (ZIRCOSOL ZA-30, manufactured by Dai- | | |
| ichi Kigenso Kagaku Kogyo Co., Ltd.) | | |

The mixed liquid was dispersed using a liquid-liquid collision type disperser (ULTIMAIZER, manufactured by Sugino Machine Limited) to prepare an intermediate dispersion liquid. The prepared intermediate dispersion liquid was heated at 45° C. and held at the temperature for 20 hours. Thus, a dispersion liquid was prepared.

<Preparation of Coating Liquid for Forming Receiving Layer>

The following materials were added to the prepared dispersion liquid and stirred and mixed to prepare a coating liquid for forming a receiving layer.

| | | |
|---|---|---|
| 5% by mass boric acid solution | 4.2 | parts by mass |
| 8.1% by mass polyvinyl alcohol solution | 16.5 | parts by mass |
| (PVA235: 7.0% by mass. PVA505: 1.1% by | | |
| mass, manufactured by KURARAY Co., | | |
| Ltd.) | | |
| Diethylene glycol monobutyl ether | 0.4 | parts by mass |
| (BUTYCENOL 20P, manufactured by | | |
| Kyowa Hakko Chemicals Co., Ltd.) | | |
| 10% by mass aqueous surfactant solution | 0.4 | parts by mass |
| (polyoxyethylene lauryl ether, EMULGEN | | |
| 109P, manufactured by Kao Corporation) | | |
| Ion exchange water | 5.9 | parts by mass |

<Preparation of In-Line Liquid>

The following materials were mixed to prepare an in-line liquid.

| | | |
|---|---|---|
| Highly basic aluminum chloride | 3.7 | parts by mass |
| (ALPINE 83, manufactured by | | |
| TAIMEI Chemical Co., Ltd.) | | |
| Ion exchange water | 6.3 | parts by mass |

<Preparation of Liquid Containing Basic Compound>

The following materials were mixed to prepare a liquid containing a basic compound.

| | | |
|---|---|---|
| Boric acid | 0.7 | parts by mass |
| Ammonium carbonate | 5 | parts by mass |
| (reagent grade 1, manufactured by | | |
| KANTO KAGAKU) | | |
| Zirconium compound | 0.3 | parts by mass |
| (ZIRCOSOL AC-7, manufactured by Dai- | | |
| ichi Kigenso Kagaku Kogyo Co.. Ltd.) | | |
| Ion exchange water | 93.4 | parts by mass |
| 10% by mass aqueous surfactant solution | 0.6 | parts by mass |
| (polyoxyethylene lauryl ether, EMULGEN | | |
| 109P, manufactured by Kao Corporation) | | |

<Formation of Receiving Layer>

The coating liquid for forming a receiving layer and the in-line liquid were in-line mixed and the mixture was applied to the surface of the protective layer 14 previously formed using an extrusion die coater.

Specifically, the coating liquid for forming a receiving layer and the in-line liquid were in-line mixed such that the coating amount of the coating liquid was 90.5 g/m² and the coating amount of the in-line liquid was 7.4 g/m², and the mixture was applied.

The formed coating layer (coating film) was dried with a hot air dryer at 80° C. (wind speed 5 m/sec) until the concentration of the solid contents reached 36% by mass. The coating layer showed constant rate drying during this period.

Immediately after drying the coating layer until the concentration of solid contents reached 36% by mass, the coating layer was immersed in the liquid containing a basic compound for 3 seconds, and 13 g/m² of the liquid containing a basic compound was applied to the coating layer having a concentration of solid contents of 36% by mass.

Further, the liquid was dried at 72° C. for 10 minutes, and thus the receiving layer 16 was formed on the surface of the protective layer 14. The thickness of the formed receiving layer 16 was 20 μm.

[Solvent Permeation Layer]

<Preparation of Coating Liquid for Forming Solvent Permeation Layer>

The following materials were mixed to prepare a coating liquid for forming a solvent permeation layer.

| | | |
|---|---|---|
| Ion exchange water | 900 | parts by mass |
| Carboxylated styrene butadiene latex | 50 | parts by mass |
| (Nipol LX433C, manufactured by Zeon | | |
| Corporation) | | |
| 10% by mass aqueous surfactant solution | 0.6 | parts by mass |

(polyoxyethylene lauryl ether, EMULGEN 109P, manufactured by Kao Corporation)

<Formation of Solvent Permeation Layer>

The coating liquid for forming a solvent permeation layer was applied to the surface of the receiving layer 16 previously formed using a #8 wire bar and dried at 40° C. for 10 minutes. Thus, the solvent permeation layer 18 was formed on the surface of the receiving layer 16 to prepare a transfer film 10.

[Production of Transfer Film B]

A transfer film B was produced in the same manner as in the production of the transfer film A except that instead of using the receiving layer 16 of the transfer film A, the following materials were used to form the receiving layer 16, and the solvent permeation layer 18 was not formed.

Specifically, the receiving layer of the transfer film B was formed as follows.

First, an ink jet receiving layer resin (product name “NS-310X”, manufactured by Takamatsu Yushi K.K., swelling type receiving layer) was prepared. Next, the ink jet receiving layer resin was applied to the surface of the protective layer 14 using an extrusion die coater such that the coating amount was 70 g/m². Thereafter, the coating film was dried at 120° C. for 5 minutes to form the receiving layer 16 on the surface of the protective layer 14. The thickness of the obtained receiving layer 16 was 9 μm.

### Example 1

First, printing using the conductive ink 1 was performed from the surface (that is, the solvent permeation layer 18) of the transfer film A opposite to the surface on which the support 12 was formed using an ink jet recording device to form a wiring pattern on the transfer film 10 (wiring pattern forming step).

Next, the surface (that is, the solvent permeation layer 18) of the transfer film 10 having the wiring pattern formed thereon opposite to the surface on which the support 12 was formed was caused to abut onto the substrate P, and the transfer film 10 and the substrate P were laminated. Next, while pressing the transfer film 10 and the substrate P, heating was performed from the support 12 side, and the transfer film 10 (solvent permeation layer 18) and the substrate P were heated and caused to adhere to each other (adhering step). The heating temperature of the transfer film 10 at the time of adhesion was 120° C.

Next, the support 12 was peeled off from the transfer film 10 caused to adhere to the substrate P (peeling step). As described above, a wiring board was produced in Example 1.

### Examples 2 to 6

Wiring boards of Examples 2 to 6 were produced in the same manner as in Example 1 except that instead of using the conductive ink 1, the conductive inks 2 to 6 were used.

However, in Example 5, the conductive ink 5 was jetted while a magnetic field was applied so that the magnetic particles were aligned in the jetting direction of the jetting head of the ink jet recording device.

### Example 7

A wiring board was produced in Example 7 in the same manner as in Example 6 except that before the transfer step, exposure was performed by irradiating the wiring pattern with ultraviolet (UV) rays using PulseForge3300 (product name, manufactured by Novacentrix Corporation).

As the exposure condition, 3 J/cm² Pulse light (1400 μSec) was emitted 10 times.

### Example 8

A wiring board was produced in Example 8 in the same manner as in Example 2 except that before the transfer step, exposure was performed by irradiating the wiring pattern with ultraviolet (UV) rays using PulseForge3300 (product name, manufactured by Novacentrix Corporation).

As the exposure condition, 3 J/cm² Pulse light (1400 μSec) was emitted 10 times.

### Example 9

A wiring board was produced in Example 9 in the same manner as in Example 2 except that instead of using the transfer film A, the transfer film B was used.

In the wiring pattern forming step using the transfer film B, printing was performed using the conductive ink 1 from the surface (that is, the receiving layer 16) of the transfer film B opposite to the surface on which the support 12 was formed. In addition, in the adhering step, on the surface (that is, the receiving layer 16) of the transfer film 10 having the wiring pattern formed thereon opposite to the surface on which the support 12 was formed was caused to abut onto the substrate P.

[Evaluation]

Using an ink jet printer (product name, “Dimatix Materials Printer DMP-2850”, manufactured by Fujifilm Corporation), 5 ml of the conductive ink was continuously jetted and then the contaminated state of the head was confirmed.

<Jetting Suitability>

The evaluation standards are as follows, and the evaluation results are shown in Table 2.

A: Nothing was attached to the head.

B: Slightly crystallized solid matter was detected on the head.

C: The wiring pattern was interrupted during printing and solid matter was attached to the head after printing.

<Resistance Value>

The resistance value of the wiring board in each example was measured.

Specifically, the jetting amount was set such that the silver amount in the conductive ink to be applied was 1.5 g/m², and the wiring board of each example having a wiring pattern of a width of 5 mm×a length of 50 mm was produced to measure the resistance values of both ends of the wiring board using a digital multimeter RD701 (product name, manufactured by Sanwa Electric Instrument Co., Ltd.).

<Durability>

The durability of the wiring board in each example was evaluated. Specifically, first, the jetting amount was set such that the silver amount in the conductive ink to be applied was 1.5 g/m², and the wiring board of each example having a wiring pattern having a size of a width of 5 mm×a length of 50 mm was produced. The obtained wiring board was held at 85° C. and 85% RH for 5 days.

The resistance values of the wiring board before and after holding were measured using a digital multimeter RD701 (product name, manufactured by Sanwa Electric Instrument Co., Ltd.). While the resistance value before holding was set to R0 and the resistance value after holding was set to R, a change rate in the resistance values before and after holding was calculated according to the following equation. The durability was evaluated by the following standards based on the obtained change rate.

(Change rate in resistance values before and after holding)=100×{(R−R0)/R0}

A: The change rate is within ±10%.

B: The change rate is more than ±10% and within ±20%.

C: The change rate is more than ±20% and within ±40%.

D: The change rate is more than ±40%.

The results of the above evaluation tests are shown in Table 2.

TABLE 2

| | Conductive ink | | | | | |
|---|---|---|---|---|---|---|
| | | | Aspect ratio of | | Mass ratio of metal | |
| | | Conductive | conductive | Migration | nanowire to | Magnetic |
| | Kind | substance | substance | inhibitor | compound (I) | particles |
| Example 1 | 1 | Silver nanowire (A) | 200 | Not contained | — | Not contained |
| Example 2 | 2 | Silver nanowire (A) | 200 | Formula (I-1) | 100 | Not contained |
| Example 3 | 3 | Silver nanowire (B) | 40 | Formula (I-1) | 100 | Not contained |
| Example 4 | 4 | Silver nanowire (C) | 2200 | Formula (I-1) | 100 | Not contained |
| Example 5 | 5 | Silver nanowire (A) | 200 | Formula (I-1) | 100 | Contained |
| Example 6 | 6 | NBSIJ-MU01 | Less than 10 | Not contained | — | Not contained |
| Example 7 | 6 | NBSIJ-MU01 | Less than 10 | Not contained | — | Not contained |
| Example 8 | 2 | Silver nanowire (A) | 200 | Formula (I-1) | 100 | Not contained |
| Example 9 | 2 | Silver nanowire (A) | 200 | Formula (I-1) | 100 | Not contained |
| Example 10 | 7 | Silver nanowire (A) | 200 | Formula (II) | 100 | Not contained |
| Example 11 | 8 | Silver nanowire (A) | 200 | Formula (I-1) | 11 | Not contained |
| Example 12 | 9 | Silver nanowire (A) | 200 | Formula (I-1) | 999 | Not contained |

| | | Step | | | | |
|---|---|---|---|---|---|---|
| | Transfer | | Heating | Evaluation result | | |
| | film | UV | temperature at | Jetting | Resistance | |
| | Kind | irradiation | adhesion step | suitability | value (Ω) | Durability |
| Example 1 | A | Not performed | 120 | B | 60 | D |
| Example 2 | A | Not performed | 120 | B | 20 | A |
| Example 3 | A | Not performed | 120 | B | 40 | A |
| Example 4 | A | Not performed | 120 | B | 15 | A |
| Example 5 | A | Not performed | 120 | A | 40 | A |
| Example 6 | A | Not performed | 120 | A | 6000 | D |
| Example 7 | A | Performed | 120 | A | 70 | D |
| Example 8 | A | Performed | 120 | B | 20 | A |
| Example 9 | B | Not performed | 120 | B | 500 | A |
| Example 10 | A | Not performed | 120 | B | 40 | B |
| Example 11 | A | Not performed | 120 | B | 30 | A |
| Example 12 | A | Not performed | 120 | B | 20 | B |

In the method of producing the wiring board in the examples, a specific transfer film in which the protective layer was formed in advance was printed. Therefore, a step of forming a protective layer was not required to be provided between the wiring pattern forming step and the adhering step and the steps from printing to adhering could be smoothly performed.

In addition, as seen from the comparison of Examples 1, 2, 11 and 12, in a case of using the conductive ink containing the compound represented by Formula (I-1) (Examples 2, 11 and 12), the durability of the wiring board was excellent.

As seen from the comparison of Examples 2 to 4, in a case where the aspect ratio of the conductive substance (silver nanowire) was 200 or more (Examples 2 to 4), the wiring board in which the resistance value of the wiring pattern was low, and the conductivity was excellent could be obtained.

As seen from the comparison of Examples 2 and 5, in a case of using the conductive ink including magnetic particles (Example 5), the jetting suitability of the ink jet recording device was excellent.

As seen from the comparison of Examples 1 and 6, in a case of using the metal nanowire (Example 1), the resistance value of the wiring pattern was low, and the durability of the wiring board was excellent.

As seen from the comparison of Examples 6 and 7 and Examples 2 and 8, in a case of exposing the wiring pattern (Examples 7 and 8), the resistance value of the wiring pattern was low.

As seen from the comparison of Examples 2 and 9, in a case of using the transfer film A having a receiving layer including receiving particles (Example 2), the resistance value of the wiring pattern was low.

As seen from the comparison of Examples 2 and 10, in a case of using the compound represented by Formula (I-1) as a migration inhibitor (Example 2), the durability of the wiring board was further excellent and the resistance value of the wiring pattern was also low.

The conductive ink 6 was prepared in the same manner as in the preparation of the conductive ink 1 except that 1 g of a dye (Direct Blue 87) was added to the conductive ink 1. As a result of conducting the same tests as in Example 1 except using the conductive ink 6, all the evaluation of the jetting stability, the resistance value, and the durability were the same as in Example 1. In addition, the wiring board was visually confirmed, and as a result, a colored wiring pattern was confirmed.

### EXPLANATION OF REFERENCES

10, X1, X2: transfer film
12, 12A, 12B: support
14, 14A, 14B: protective layer
16, 16A, 16B: receiving layer
18, 18A, 18B: solvent permeation layer
20: receiving particles
24: surface
26: thermoplastic resin particles
28: tackifier particles
100, 200, 300: wiring board
L: gap
P: substrate

What is claimed is:

1. A method of producing a wiring board using a transfer film including
a support,
a protective layer that is formed on one surface of the support and is peelable from the support, and
a receiving layer that is formed on a surface of the protective layer and receives a solvent in a conductive ink including a conductive substance and the solvent, the method comprising:
a wiring pattern forming step of forming a wiring pattern on the transfer film by performing printing using the conductive ink from a surface of the transfer film opposite to a surface on which the support is formed;
an adhering step of, after the wiring pattern forming step, causing the surface of the transfer film having the wiring pattern formed thereon opposite to the surface on which the support is formed to abut onto a substrate and causing the transfer film to adhere to the substrate; and
a peeling step of, after the adhering step, peeling off the support from the transfer film caused to adhere to the substrate to obtain a wiring board.

2. The method of producing a wiring board according to claim 1,
wherein the transfer film further includes a solvent permeation layer that is formed on a surface of the receiving layer and has a void for allowing permeation of the solvent.

3. The method of producing a wiring board according to claim 1,
wherein the printing is performed by an ink jet method.

4. The method of producing a wiring board according to claim 1,
wherein the adhering step is performed under heating.

5. The method of producing a wiring board according to claim 4,
wherein a heating temperature in the adhering step is 80° C. or higher.

6. The method of producing a wiring board according to claim 1,
wherein a procedure in which a new transfer film on which the wiring pattern obtained by the wiring pattern forming step is formed is caused to adhere to the wiring board obtained in the peeling step, and then the support in the new transfer film is peeled off is repeatedly performed so that a plurality of wiring patterns are laminated on the substrate.

7. The method of producing a wiring board according to claim 1,
wherein, after the wiring pattern forming step, the wiring pattern is exposed to light.

8. The method of producing a wiring board according to claim 1,
wherein the conductive substance is a metal nanowire having an aspect ratio of 200 or more.

9. The method of producing a wiring board according to claim 1,
wherein the conductive ink further includes a compound represented by Formula (I), 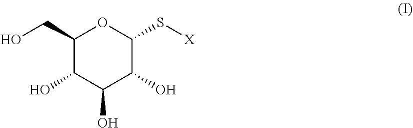
in Formula (I), X represents a gold atom, a palladium atom, or a platinum atom.

10. The method of producing a wiring board according to claim 9,
wherein the conductive substance is a metal nanowire having an aspect ratio of 200 or more, and
a mass ratio of the metal nanowire with respect to the compound represented by Formula (I) is more than 10 and less than 1000.

11. The method of producing a wiring board according to claim 1,
wherein the conductive ink further includes magnetic particles.

12. The method of producing a wiring board according to claim 1,
wherein the conductive ink further includes a coloring material.

13. A conductive ink comprising:
a solvent;
a compound represented by Formula (I); and
a metal nanowire having an aspect ratio of 200 or more, 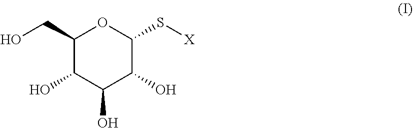
in Formula (I), X represents a gold atom, a palladium atom, or a platinum atom.

14. The conductive ink according to claim 13,
wherein a mass ratio of the metal nanowire with respect to the compound represented by Formula (I) is more than 10 and less than 1000.

15. The conductive ink according to claim 13, further comprising:
magnetic particles.

16. The conductive ink according to claim 13, further comprising:
a coloring material.

17. The method of producing a wiring board according to claim 2,
wherein the printing is performed by an ink jet method.

18. The method of producing a wiring board according to claim 2,
wherein the adhering step is performed under heating.

19. The method of producing a wiring board according to claim 3,
wherein the adhering step is performed under heating.

20. The method of producing a wiring board according to claim 2,
wherein a procedure in which a new transfer film on which the wiring pattern obtained by the wiring pattern forming step is formed is caused to adhere to the wiring board obtained in the peeling step, and then the support in the new transfer film is peeled off is repeatedly performed so that a plurality of wiring patterns are laminated on the substrate.
